(19) United States
(12) Patent Application Publication
(10) Pub. No.: US 2022/0282378 A1
(43) Pub. Date: Sep. 8, 2022

(54) SHIELDING MECHANISM AND SUBSTRATE-PROCESSING DEVICE WITH THE SAME

(71) Applicant: SKY TECH INC., Hsinchu County (TW)

(72) Inventors: JING-CHENG LIN, Hsinchu County (TW); TA-HAO KUO, Hsinchu County (TW); CHI-HUNG CHENG, Hsinchu County (TW); YU-TE SHEN, Hsinchu County (TW)

(21) Appl. No.: 17/355,020

(22) Filed: Jun. 22, 2021

(30) Foreign Application Priority Data
Mar. 8, 2021 (TW) 110108086

(51) Int. Cl. C23C 16/48; C23C 16/458; C23C 16/455

(52) U.S. Cl. CPC C23C 16/488; C23C 16/4584; C23C 16/45525

(57) ABSTRACT

The present disclosure is a substrate-processing chamber with a shielding mechanism with the same, which includes a reaction chamber, a substrate carrier, a storage chamber and a shielding mechanism. The reaction chamber is connected to the storage chamber, the substrate carrier is within the reaction chamber. The shielding mechanism includes at least one driving shaft, at least one connecting seat and a shield, wherein the driving shaft extends from the storage chamber to the reaction chamber. The connecting seat is connected to the shield and the driving shaft, wherein the driving shaft drives the shield to move between the storage chamber and the reaction chamber, via the connecting seat.

### TECHNICAL FIELD

The present disclosure relates to a shielding mechanism and a substrate-processing chamber with the same, which mainly employs the shielding mechanism to isolate a reaction space of a reaction chamber from a substrate carrier, to prevent polluting the substrate carrier during a process of cleaning the reaction chamber.

### BACKGROUND

Thin-film-deposition equipments, such as chemical-vapor deposition (CVD), physical-vapor deposition (PVD) and the atomic-layer deposition (ALD) equipments, those are commonly employed in manufacturing process of semiconductors, light-emitting diodes and displays, etc.

A thin-film-deposition equipment mainly includes a chamber and a substrate carrier, wherein the substrate carrier is within the chamber for carrying at least one substrate. To exemplify by PVD, a target material is required to dispose within the chamber, wherein the target material faces the substrate on the substrate carrier. When performing PVD, noble gas or reactive gas is transferred into the chamber, then bias electricity is applied on the target material and the substrate carrier respectively, also the substrate carried on by the substrate carrier is heated up.

The noble gas or reactive gas within the chamber transforms into ionized gas in effect of a high-voltage electric field, then the ionized gas is attracted by the bias electricity to bombard the target material. Thereby, atoms or molecules splashed from the target material are attracted by the bias electricity on the substrate carrier, then be deposited on surface of the substrate and forms a thin film on the surface of the substrate.

After some time of usage, an inner surface of the chamber may also be formed with thin film, then a periodic cleaning is required to perform to the chamber, in order to prevent the waste thin film from dropping onto the substrate and causing pollution during the process of thin-film deposition. Moreover, surface of the target material may be formed with oxide or other pollutant, therefore requires a periodic cleaning as well. Generally, a burn-in process is applied to bombard the target material within the chamber by plasma ions, then to remove the oxides or pollutants on the surface of target material.

To perform the abovementioned cleaning process, the substrate carrier and the substrate must be extracted or kept out, to prevent the removed pollutant from turning to pollute the substrate carrier and the substrate, during the cleaning process.

### SUMMARY

Generally, after some time of usage, the substrate-processing device is required for cleaning, in order to remove the waste thin film within the chamber and the oxide or nitride on the target material. During the cleaning process, some removed pollutant particles may turn to pollute the substrate carrier, thus there is a need to keep out the substrate carrier from the removed pollutant. The present disclosure provides a shielding mechanism and a substrate-processing device with the same, which mainly employs a driving shaft to drive a shield moving along with the driving shaft between a storage state and a shielding state, such that to prevent the removed pollutant particles from turning to pollute the substrate carrier during the process of cleaning the chamber or the target material.

According to one object of the present disclosure, which is to provide a substrate-processing device with a shielding mechanism. The substrate-processing device mainly includes a reaction chamber, a substrate carrier, a storage chamber and the shielding mechanism, wherein the storage chamber is connected to the reaction chamber. The shielding mechanism includes a driving shaft, a connecting seat and a shield, wherein the driving shaft is connected to the shield via the connecting seat, and drives the shield to move between the storage chamber and the reaction chamber.

During the process of cleaning the reaction chamber, the driving shaft drives the shield to move into the reaction chamber and to cover the substrate carrier within the reaction space, for preventing the plasma or the removed pollutant from contacting the substrate carrier and/or the substrate carried on thereby. When performing a deposition process, the driving shaft drives the shield to move into the storage chamber, and allows the reaction chamber to operate a thin-film deposition to the substrate.

One object of the present disclosure is to provide the abovementioned substrate-processing device, wherein the driving shaft becomes two respectively connected to two sides of the shield. By virtue of the two driving shafts, the shield can be carried more steadily for a stable movement, also the shield with greater thickness and a heavier mass is applicable. By virtue of the thicker and heavier shield, which is more durable against a deformation caused by the process of cleaning the chamber, and which can further prevent the plasma or the removed pollutant from sneaking through the deform shield and contacting the substrate carrier or the substrate.

Furthermore, two jacket members may be disposed to respectively jacket the two driving shafts, for preventing tiny particles from spreading into a containing space of the reaction chamber, wherein the tiny particles are created as the driving shafts drive the shield to move. Also, a distance between the two driving shafts and a distance between the two jacket members, which are all greater than a diameter of the substrate carrier and a diameter of the substrate thereon, such that to avoid interfering and disrupting a movement of the substrate carrier and the performance of the deposition process.

One object of the present disclosure is to provide the abovementioned substrate-processing device, wherein the jacket members are made of electrical conductors and electrically connected to a bias unit. The bias unit is for generating bias electricity on the jacket members, to attract the tiny particles created as the driving shaft drives the connecting seat and the shield, and to prevent the tiny particles from entering the containing space of the reaction chamber.

One object of the present disclosure is to provide the abovementioned substrate-processing device, wherein the jacket member has an isolating space fluidly connected to a suction unit. The suction unit is for extracting out air or gas and the tiny particles within the isolating space, to prevent the tiny particles from entering the containing space of the reaction chamber.

To achieve the abovementioned objects, the present disclosure provides a substrate-processing device, which includes a reaction chamber, a substrate carrier, a storage chamber, a shielding mechanism. The reaction chamber includes a containing space. The substrate carrier is positioned within the containing space, for carrying at least one substrate. The storage chamber is connected to the reaction chamber, wherein the storage chamber comprises a storage space that is fluidly connected to the containing space. The shielding mechanism includes: at least one driving shaft extending from the storage space to the containing space; at least one connecting seat connected to the driving shaft; and a shield connected to the connecting seat. The driving shaft moves the shield via the connecting seat to move between the storage space and the containing space, wherein the shield moves in a direction parallel to that of the driving shaft.

The present disclosure also provides a shielding mechanism adapted to be used in a substrate-processing device, which includes: at least one driving shaft; at least one connecting seat connected to the driving shaft; and a shield connected to the connecting seat. The driving shaft rotates to move the connecting seat and the shield along the driving shaft, wherein the shield moves in a direction parallel to the driving shaft.

### BRIEF DESCRIPTION OF THE DRAWINGS

The structure as well as preferred modes of use, further objects, and advantages of this present disclosure will be best understood by referring to the following detailed description of some illustrative embodiments in conjunction with the accompanying drawings, in which:

FIG. 1 is a schematic perspective sectional view illustrating a shielding state of a substrate-processing device, according to one embodiment of the present disclosure.

FIG. 2 is a schematic perspective sectional view illustrating a storage state of a substrate-processing device, according to one embodiment of the present disclosure.

FIG. 3 is a schematic fragmentary sectional view of a shielding mechanism of the substrate-processing device, according to one embodiment of the present disclosure.

FIG. 4 is a schematic side sectional view illustrating the shielding state of the substrate-processing device, according to one embodiment of the present disclosure.

FIG. 5 is a schematic side sectional view illustrating the storage state of the substrate-processing device, according to one embodiment of the present disclosure.

FIG. 6 is a schematic top sectional view illustrating the shielding state of the substrate-processing device, according to one embodiment of the present disclosure.

FIG. 7 is a schematic top sectional view illustrating the storage state of the substrate-processing device, according to one embodiment of the present disclosure.

FIG. 8 is a schematic perspective sectional view of the substrate-processing device, according to another embodiment of the present disclosure.

FIG. 9 is a schematic perspective sectional view of the substrate-processing device, according to another different embodiment of the present disclosure.

FIG. 10 is a schematic sectional view of the substrate-processing device, according to another different embodiment of the present disclosure.

### DETAILED DESCRIPTION OF THE PREFERRED EMBODIMENTS

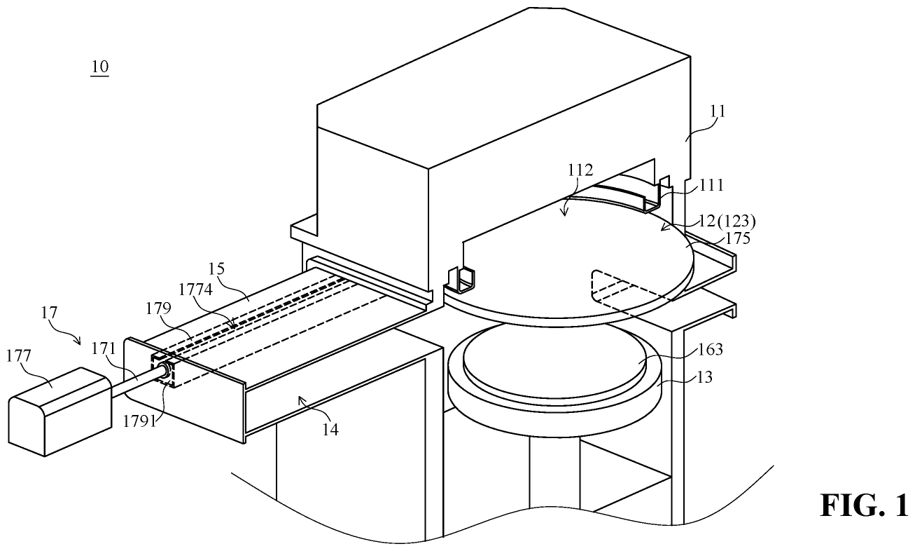

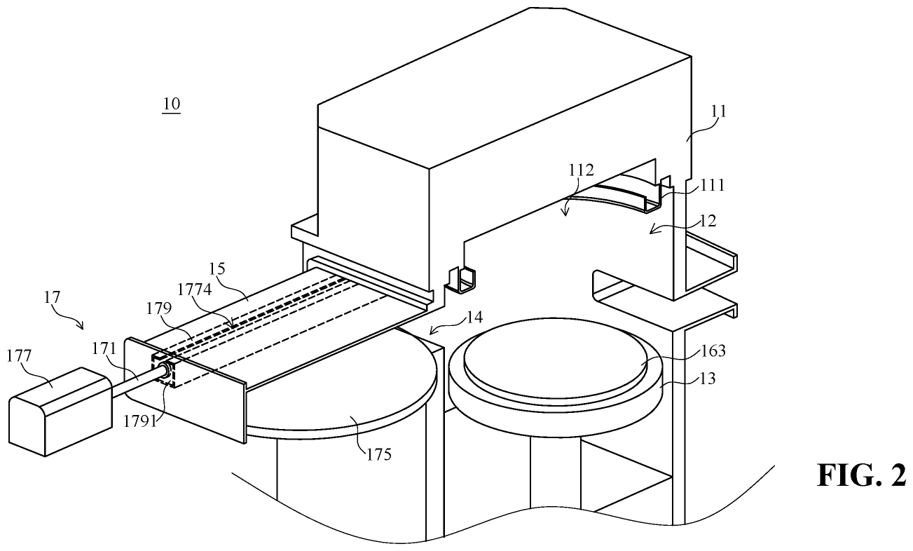

Referring to FIG. 1 and FIG. 2, which are schematic perspective sectional views respectively illustrating a shielding state, and a storage state of a substrate-processing device 10, according to one embodiment of the present disclosure. As shown in FIGs, the substrate-processing device 10 mainly includes a reaction chamber 11, a substrate carrier 13, a storage chamber 15 and a shielding mechanism 17. The reaction chamber 11 is connected to the storage chamber 15, and the substrate carrier 13 is disposed within the reaction chamber 11.

The reaction chamber 11 has a containing space 12 for containing the substrate carrier 13. The storage chamber 15 is connected to the reaction chamber 11 and has a storage space 14, wherein the storage space 14 is fluidly connected to the containing space 12 for containing and storing the shield 175.

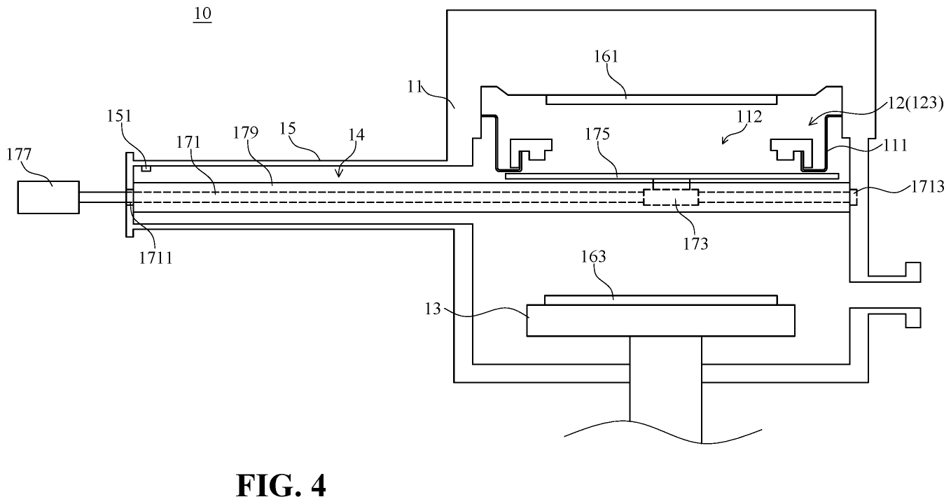

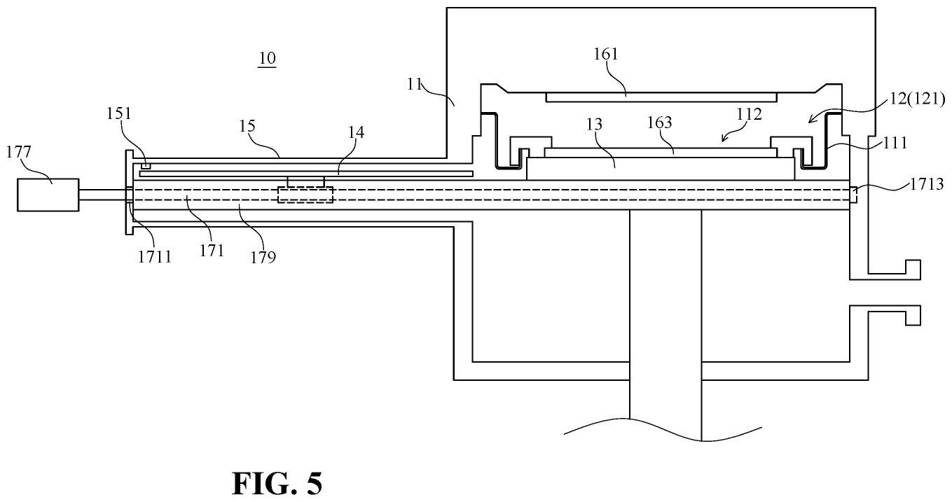

The substrate carrier 13 is positioned within the containing space 12 of the reaction chamber 11, for carrying at least one substrate 163. In this embodiment, the substrate-processing device 10 is exemplified as a physical-vapor-deposition (PVD) chamber, and as shown in FIG. 4 and FIG. 5, the reaction chamber 11 is disposed with a target material 161 therein, wherein the target material 161 faces the substrate 163 and the substrate carrier 13.

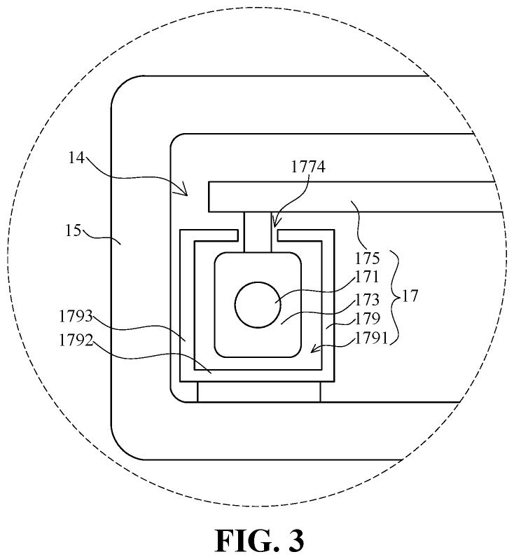

Referring to FIG. 3, the shielding mechanism 17 includes at least one driving shaft 171, at least one connecting seat 173 and a shield 175. The connecting seat 173 interconnects the shield 175 and the driving shaft 171, furthermore the shield 175 and the connecting seat 173 are able to movable relative to the driving shaft 171.

In one embodiment according to the present disclosure, the driving shaft 171 may be a leadscrew, wherein the driving shaft 171 has a surface formed with a screw thread. The connecting seat 173 includes a threaded portion or a threaded hole engaged with the screw thread on the surface of the driving shaft 171. The driving shaft 171 can rotate to drive the connecting seat 173 and the shield 175 moving along the driving shaft 171 itself, and also moving between the storage space 14 and the containing space 12. Thereby, the shield 175 moves in a direction parallel to an axial direction of the driving shaft 171.

In practical use, the driving shaft 171 may be connected to a drive unit 177, for driving the driving shaft 171 to rotate thereby. The drive unit 177 may be such as a motor or a stepper motor.

In one embodiment according to the present disclosure, the driving shaft 171 extends from the storage space 14 of the storage chamber 15 to the containing space 12 of the reaction chamber 11. For example, in this embodiment, the storage chamber 15 has a wall surface facing a wall surface of the reaction chamber 11, and the driving shaft 171 extends from the wall surface of the storage chamber 15 to the wall surface of the reaction chamber 11. The driving shaft 171 may extend through the wall surface of the storage chamber 15 or the wall surface of the reaction chamber 11, and be connect to the drive unit 177 which is disposed outside of the storage chamber 15 and the reaction chamber 11.

Specifically, the driving shaft 171 may be disposed on the wall surface of the storage chamber 15 via a bearing, or even a magnetic-liquid-rotary seal 1711. Thereby when the drive unit 177 drives the driving shaft 171 to rotate related to the storage chamber 15, the rotation of the driving shaft 171 does not affect a vacuum condition within the containing space 12 and the storage space 14. In addition, the driving shaft 171 may have an end disposed on the wall surface of the storage chamber 15, and another end connected to the wall surface the reaction chamber 11 via another bearing 1713.

In the abovementioned embodiment according to the present disclosure, the driving shaft 171 extends through the wall surface of the storage chamber 15, and be connected to the drive unit 177 adjacent to the storage chamber 15. In another embodiment according to the present disclosure, the driving shaft 171 may be reconfigured to extend through the wall surface of the reaction chamber 11 instead, and to be connected to the drive unit 177 which is disposed adjacent to the reaction chamber 11.

The substrate-processing device 10 according to the present disclosure is operable in two states, as a storage state and a shielding state. The drive unit 177 can drive the driving shaft 171 to move the connecting seat 173 and the shield 175 into the storage space 14 of the storage chamber 15, such that the substrate-processing device 10 operates in the storage state. As shown in FIG. 2 and FIG. 5, the shield 175 does not get between the target material 161 and the substrate carrier 13 with the substrate 163 thereon.

Thereafter, the substrate carrier 13 and the substrate 163 thereon can be driven by an elevating unit (not shown) to move and approach the target material 161. Then, a process gas such as noble gas, which is disposed within the containing space 12, and controlled to bombard the target material 161, such that to perform a thin-film deposition on a surface of the substrate 163.

In one embodiment according to the present disclosure, the containing space 12 of the reaction chamber 11 may be disposed with a blocking member 111, wherein the blocking member 111 has an end connected to the reaction chamber 11 and another end formed with an opening 112. When the substrate carrier 13 is driven to approach the target material 161, the substrate carrier 13 also enters or contacts the opening 112 of blocking member 111, such that the reaction chamber 11, the substrate carrier 13 and the blocking member 111 together define a reacting space 121 within the containing space 12, thereby to prevent forming undesired thin film on other portions of the reaction chamber 11 and the substrate carrier 13 those are outside of the reacting space 121, during the thin-film deposition process.

Otherwise, the drive unit 177 may drive the driving shaft 171 to move the connecting seat 173 and the shield 175 to the containing space 12 of the reaction chamber 11, such that the substrate-processing device 10 operates in the shielding state, as shown in FIG. 1 and FIG. 4. Thereby, the shield 175 is positioned between the target material 161 and the substrate 163 with the substrate carrier 13, for isolating the target material 161 from the substrate 163 and substrate carrier 13.

The shield 175 in the shielding state can define a cleaning space 123 within the containing space 12, wherein the containing space 12 and the reacting space 121 may spatially overlap with reacting space 121 partially or entirely. The containing space 12 may perform a burn-in process therein, which applies plasma to bombard, clean the target material 161, a portion of the reaction chamber 11 and/or the blocking member 111 within the cleaning space 123, and to remove some oxide or pollutant on a surface of the target material 161, also to remove some undesired, waste thin film on surfaces of the reaction chamber 11 and/or the blocking member 111.

During a process of cleaning the substrate-processing device 10, the substrate carrier 13 and/or the substrate 163 is covered or kept away by the shield 175, to prevent the removed pollutant from turning to pollute or deposit on surface of the substrate carrier 13 and/or the substrate 163 thereon.

The shield 175 according to the present disclosure commonly has a plate-shaped appearance, such as a round plate but not limited thereto. The shield 175 has an area larger than that of the opening 112 formed on the blocking member 111 and/or the substrate carrier 13.

In one embodiment according to the present disclosure, the shielding mechanism 17 may include just one driving shaft 171 and one connecting seat 173, wherein the driving shaft 171 is connected to a side of the shield 175 via the connecting seat 173. Such that, the driving shaft 171 does not spatially overlap with or interfere the opening 112 of the blocking member 111, the substrate 163 and/or the substrate carrier 13, in order to avoid disrupting the movement of the substrate carrier 13 and the thin-film deposition process.

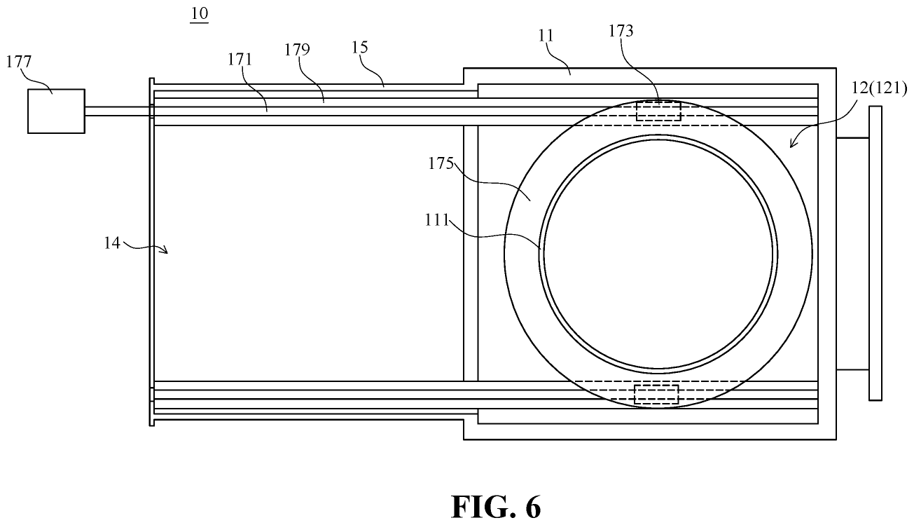

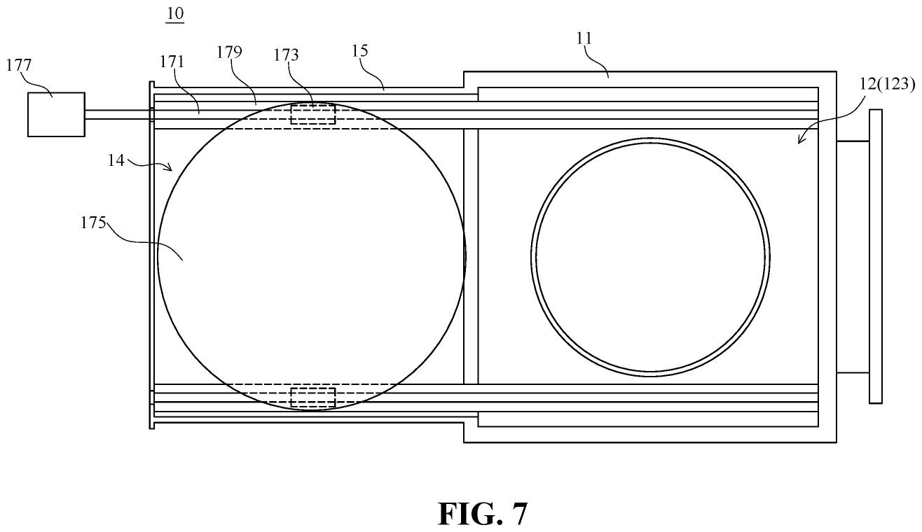

In another embodiment according to the present disclosure, as shown in FIG. 6 and FIG. 7, the shielding mechanism 17 may include may include two driving shafts 171 and two connecting seats 173, wherein the two driving shafts 171 are respectively connected to two sides of the shield 175 via the two connecting seats 173. Similar to the aforementioned embodiment, the two driving shafts 171 do not spatially overlap with or interfere the opening 112 of blocking member 111, the substrate 163 and/or the substrate carrier 13. To be specific, the two driving shafts 171 have a perpendicular distance therebetween, which is greater than maximum lengths (e. g. maximum diameters) of the opening 112 of the blocking member 111, the substrate 163 and/or the substrate carrier 13. Therefore, the driving shafts 171 do not disrupt the movement of the substrate carrier 13 and the thin film deposition process.

Specifically, when number of driving shaft 171 and number of the connecting seat 173 are two or more, these can aid to carry and move the shield 175 in a more stable manner. Besides, by virtue of employing two the driving shafts 171 and two connecting seats 173, these can also facilitate for carrying a thicker or heavier shield 175. The thicker and heavier shield 175 can resist thermal deformation caused by the burn-in cleaning process of the substrate-processing device 10, and thereby to prevent the shield 175 from deforming and allowing some of the plasma to sneak through, then to contact the substrate carrier 13 or the substrate 163 below.

When the driving shaft 171 is plural, one of the driving shaft 171 may be configured to connect the drive unit 177, whereas another one of the driving shaft 171 does not. To be specific, the driving shaft 171 connected to the drive unit 177 may be a leadscrew, whereas the another driving shaft 171 that is not connected to the drive unit 177 may be a rod 171 with no screw thread.

When the drive unit 177 drives the driving shaft 171 as the leadscrew to rotate, such that to drive the driving shaft 171 to move a corresponding one of the connecting seats 173 and the shield 175 along the axial direction of the driving shaft 171, and thereby the moving shield 175 brings the another connecting seat 173 to move together along the another driving shaft 171 as the rod. In other words, the driving shaft 171 as the leadscrew is for driving the shield 175 to move, where the another driving shaft 171 as the rod is for carrying and guiding the shield 175 to move.

When number the drive unit 177 is one, the drive unit 177 may interconnect and drive two driving shafts 171 both as leadscrews to synchronously rotate, via a synchro mechanism. In a different embodiment, the drive unit 177 may also be two respectively connected to the two driving shafts 171 as the leadscrews, to respectively drive the two driving shafts 171 to rotate.

In one embodiment according to the present disclosure, the shielding mechanism 17 may include at least one jacket member 179, wherein the jacket member 179 is positioned within the containing space 12 and the storage space 14, for jacketing the driving shaft 171 and the connecting seat 173. Specifically, the jacket member 179 may have a long bar-like appearance, which extends from the wall surface of the storage chamber 15 to the opposite wall surface of the reaction chamber 11.

The jacket member 179 has an isolating space 1791, wherein the driving shaft 171 and the connecting seat 173 are positioned within the isolating space 1791. By virtue of disposing the jacket member 179, when some tiny particles are created as the driving shaft 171 drives the connecting seat 173 and the shield 175 move, the jacket member 179 can prevent the tiny particles from falling and spreading into the containing space 12 and/or the storage space 14, thereby to maintain cleanliness of the containing space 12 within the reaction chamber 11.

The jacket member 179 extends from the storage space 14 to the containing space 12, and includes a bottom portion 1792 and two lateral portions 1793, as shown in FIG. 3. The two lateral portions 1793 are respectively connected to two lateral sides of the bottom portion 1792, such that the bottom portion 1792 and the two lateral portions 1793 together have a U-shaped sectional view and form the isolating space 1791 therebetween. Furthermore, the jacket member 179 has a top portion disposed with a long gap 1794, and the connecting seat 173 moves along the gap 1794.

In one embodiment according to the present disclosure, the storage chamber 15 may be further disposed with at least one position-sensor unit 151. The position-sensor unit 151 is disposed to face the storage space 14, for detecting if the shield 175 entered the storage space 14 or not. The position-sensor unit 151 may be an optical position sensor, for example.

If the substrate carrier 13 moves toward the target material 161 when the shield 175 is still within the containing space 12 of the reaction chamber 11, the substrate carrier 13 may hit the shield 175 then cause damage the substrate carrier 13 itself and/or the shield 175. In practical use, the substrate-processing device 10 may be configured as to permit the substrate carrier 13 to move and approach the target material 161, only when the position-sensor unit 151 detects and conforms that the shield 175 has entered the storage chamber 15 entirely, such that to avoid a collision between the substrate carrier 13 and the shield 175.

In another embodiment according to the present disclosure, the reaction chamber 11 may be disposed with the position-sensor unit 151, which faces the containing space 12 of the reaction chamber 11, for detecting if the shield 175 is still within the containing space 12. To be specific, the position-sensor unit 151 may be disposed to detect and confirm if the shield 175 has entirely entered the storage chamber 15 and/or moved out of the reaction chamber 11, it is only sufficient for the position-sensor unit 151 to detect a position of the shield 175, therefore a disposing manner or type of the position-sensor unit 151 does not limit claim scope of the present disclosure.

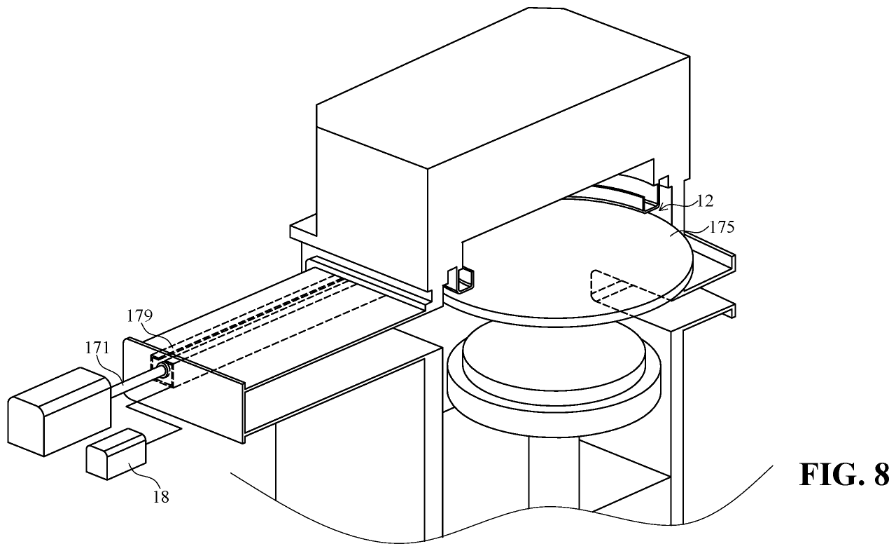

In one embodiment according to the present disclosure as shown in FIG. 8, the jacket member 179 may be made of electrical conductor, such as metal. The jacket member 179 is electrically connected to a bias unit 18, wherein the bias unit 18 is for generating a bias electricity on the jacket member 179. The tiny particles created when the driving shaft 171 drives the connecting seat 173 and the shield 175 to move, which are usually electrified and hence attracted by the bias electricity on the jacket member 179.

By virtue of generating the bias electricity on the jacket member 179, which can further attract, collect and keep the tiny particles within the jacket member 179, such that to prevent the tiny particles from spreading into the containing space 12. In practical use, the substrate-processing device 10 may be configured as the bias unit 18 only supplies the bias electricity to the jacket member 179, when the driving shaft 171 drives the connecting seat 173 and the shield 175 to move.

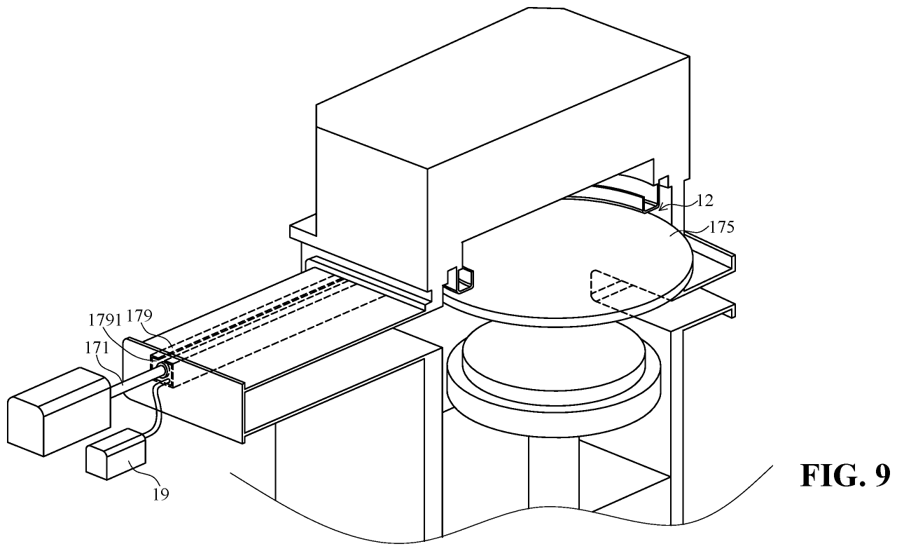

In another embodiment according to the present disclosure as shown in FIG. 9, a suction unit 19 is fluidly connected to the isolating space 1791 of the jacket member 179, wherein the suction unit 19 may be an independent, additional component. The suction unit 19 is for extracting air or gas within the isolating space 1791, for creating a negative pressure therein. The tiny particles created within the isolating space 1791 when the driving shaft 171 drives the connecting seat 173 and the shield 175 to move, which can be extracted and removed by the suction unit 19, such that to prevent polluting the containing space 12.

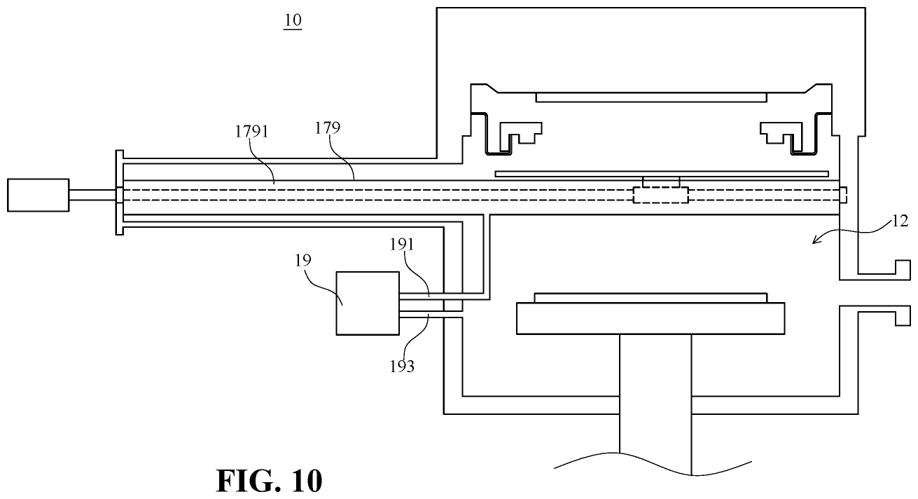

The suction unit 19 may also be a preset component of the substrate-processing device 10, as shown in FIG. 10. The suction unit 19 is connected to the isolating space 1791 of the jacket member 179 via a suction pipe 191, and also connected to the reacting space 121 via a vacuum pipe 193.

To be specific, when the driving shaft 171 drives the connecting seat 173 and the shield 175 to move, the suction unit 19 extracts the air or gas within the isolating space 1791 via the suction pipe 191. Furthermore, when performing the thin-film deposition, the suction unit 19 can also extract air or gas within the reacting space 121 via the vacuum pipe 193, thereby to create a vacuum condition within the reacting space 121. Moreover, one or each of the suction pipe 191 and the vacuum pipe 193 has an end which is connected to suction unit 19, and which may be disposed with a filter unit (not shown) for preventing the tiny particles within the isolating space 1791 from entering the suction unit 19.

The above disclosure is only the preferred embodiment of the present disclosure, and not used for limiting the scope of the present disclosure. All equivalent variations and modifications on the basis of shapes, structures, features and spirits described in claims of the present disclosure should be included in the claims of the present disclosure.

We claim:

1. The substrate-processing device, comprising:
a reaction chamber comprising a containing space;
a substrate carrier positioned within the containing space for carrying at least one substrate;
a storage chamber connected to the reaction chamber, wherein the storage chamber comprises a storage space that is fluidly connected to the containing space; and
a shielding mechanism comprising
at least one driving shaft that extends from the storage space to the containing space,
at least one connecting seat that is connected to the at least one driving shaft, and
a shield that is connected to the at least one connecting seat, wherein the at least one driving shaft moves the shield between the storage space and the containing space via the at least one connecting seat, and wherein the shield moves parallel to the at least one driving shaft.

2. The substrate-processing device according to claim 1, further comprising a drive unit and a magnetic-liquid-rotary seal, wherein the at least one driving shaft is disposed on the storage chamber or the reaction chamber via the magnetic-liquid-rotary seal, the drive unit is connected to the at least one driving shaft for driving the at least one driving shaft to rotate and to move the at least one connecting seat along the at least one driving shaft.

3. The substrate-processing device according to claim 2, wherein the at least one driving shaft is a leadscrew, the at least one connecting seat comprises a threaded hole or a threaded portion, and the at least one connecting seat is connected to the leadscrew via the threaded hole or the threaded surface.

4. The substrate-processing device according to claim 2, wherein each of the at least one driving shaft and the at least one connecting seat is two, both of the driving shafts are respectively connected to two sides of the shield via both of the connecting seats, and wherein the driving shafts have a distance therebetween, the distance is greater than a maximum diameter of the substrate and the substrate carrier.

5. The substrate-processing device according to claim 4, wherein one of the driving shafts is connected to the drive unit, another one of the driving shafts is not connected to the drive unit, the one of the driving shafts connected to the drive unit is a leadscrew, the connecting seat connected to the leadscrew comprises a threaded hole or a threaded portion, and the another one of the driving shafts is a rod.

6. The substrate-processing device according to claim 1, wherein the storage chamber or the reaction chamber is disposed with at least one position-sensor unit, for detecting a position of the shield.

7. The substrate-processing device according to claim 1, further comprising a target material that is disposed within the containing space and that faces the substrate carrier, wherein the shield moving to the containing space is positioned between the target material and the substrate carrier.

8. The substrate-processing device according to claim 1, further comprising a blocking member that is disposed within the containing space of the reaction chamber, wherein the blocking member has an end connected to the reaction chamber, and an another end formed with an opening.

9. The substrate-processing device according to claim 8, wherein the substrate carrier entering the opening of the blocking member, the reaction chamber and the blocking member together define a reacting space within the containing space.

10. The substrate-processing device according to claim 8, wherein the shield has an area larger than the opening formed on the blocking member, the shield within the containing space and the blocking member together define a cleaning space within the containing space.

11. The substrate-processing device according to claim 1, further comprising at least one jacket member that is positioned within both of the containing space and the storage space, and that comprises an isolating space, wherein the at least one driving shaft and the at least one connecting seat are positioned within the isolating space of the jacket member.

12. The substrate-processing device according to claim 11, wherein the at least one jacket member comprises a bottom portion and two lateral portions, the two lateral portions are respectively connected to two lateral sides of the bottom portion and together define the isolating space therebetween.

13. The substrate-processing device according to claim 11, wherein the jacket member is made of an electrical conductor and is electrically connected to a bias unit.

14. The substrate-processing device according to claim 11, wherein further comprising a suction unit that is fluidly connected to the isolating space of the jacket member, for extracting a gas within the isolating space.

15. A shielding mechanism adapted to be used in a substrate-processing device, comprising:
at least one driving shaft;
at least one connecting seat connected to the at least one driving shaft; and
a shield connected to the at least one connecting seat, wherein the at least one driving shaft rotates to move the at least one connecting seat and the shield along the at least one driving shaft, and wherein the shield moves parallel to the at least one driving shaft.

16. The shielding mechanism according to claim 15, further comprising a drive unit that is connected to the at least one driving shaft and that drives the at least one driving shaft to rotate, for moving the at least one connecting seat along the at least one driving shaft.

17. The shielding mechanism according to claim 16, wherein the at least one driving shaft is a leadscrew, the at least one connecting seat comprises a threaded hole or a threaded portion, and the at least one connecting seat is connected to the leadscrew via the threaded hole or the threaded portion.

18. The shielding mechanism according to claim 15, further comprising at least one jacket member that jackets the at least one driving shaft and the at least one connecting seat, and that has an isolating space for containing the at least one driving shaft and the at least one connecting seat therein.

19. The shielding mechanism according to claim 18, wherein the at least one jacket member is made of an electrical conductor, and is electrically connected to a bias unit.

20. The shielding mechanism according to claim 18, further comprising a suction pipe that is fluidly connected to the isolating space of the jacket member, for extracting a gas within the isolating space.
